(19) United States
(12) Patent Application Publication
(10) Pub. No.: US 2026/0182009 A1
(43) Pub. Date: Jun. 25, 2026

(54) INTEGRATED CIRCUIT HAVING FIN AND PLANAR BOUNDARY STRUCTURE AND METHOD OF FORMING THE SAME

(71) Applicant: Taiwan Semiconductor Manufacturing Company, LTD., Hsinchu (TW)

(72) Inventors: Fu-Hsiung Yang, Zhongli (TW); Yu-Chih Chen, Taoyuan (TW); Szu-Hsien Liu, Zhubei (TW)

(21) Appl. No.: 18/989,670

(22) Filed: Dec. 20, 2024

(51) Int. Cl. H10D 84/83; H01L 23/58; H10D 84/01

(52) U.S. Cl. CPC H10D 84/834; H10D 84/0151; H10D 84/0158; H10W 42/00

(57) ABSTRACT

A semiconductor structure and method of fabricating same structure includes forming, in a device region of a semiconductor substrate, a fin region including one or more fin field-effect transistors (finFETs), each device region finFET including one or more fins formed to have a fin top at a first height from a finFET base region adjacent to the finFET fin; and forming a high voltage (HV) planar region adjacent to the fin region. The HV planar region including a first HV planar region at a second height from the finFET base region, the second height greater than the first height, and the HV planar region including a second HV planar region having a HV isolation structure isolating the first HV planar region from the fin region, the HV isolation structure including a boundary buffer area having an intermediate step at a third height from the finFET base region that is equal to or greater than the first height and less than the second height.

### BACKGROUND

The following relates to semiconductor integrated circuits (ICs) employing a fin field-effect transistor (finFET) or other three-dimensional (3D) semiconductor structure including a fin and planar boundary, and to the manufacturing thereof.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross sectional view of an integrated circuit (IC) structure (Embodiment 1) including a finFET region, an interconnected high voltage (HV) left planar region including a left planer region to fin region buffer boundary area, and an interconnected low/medium voltage (L/MV) right planar region including a right planar region buffer boundary area according to an example embodiment of the present disclosure.

FIG. 1B is a detailed cross sectional view of the left planar region boundary buffer area of the IC structure (Embodiment 1) shown in FIG. 1A according to an example embodiment of the present disclosure.

FIG. 1C is a detailed cross sectional view of the right planar region boundary buffer area of the integrated circuit IC structure (Embodiment 1) shown in FIG. 1A, including depicting the slope of the boundary buffer area relative to the height of a HV planar region and a LV finFET region (Embodiment 1) according to an example embodiment of the present disclosure.

FIG. 2A is a top view of a wafer including an IC structure including a chip/IC/device planar region adjacent to a seal ring encircling the chip, the seal ring including an outer seal ring dummy, a fin type middle seal ring wall and a planar inner seal region, i.e. seal ring enhanced zone (SREN), the planar inner seal region including a boundary buffer area according to an example embodiment of the present disclosure (Embodiment 2), the boundary buffer area abating a step height from the seal ring wall fins to a planar region adjacent the planar inner seal boundary buffer area of the chip.

FIG. 2B is a detailed top view of a wafer including an integrated circuit (IC) structure as shown in FIG. 2A, this figure showing details of the outer seal ring dummy structure, the middle seal ring wall fin structure, and the inner seal ring boundary buffer area structure according to an example embodiment of the present disclosure (Embodiment 2).

FIG. 2C is a cross sectional view of the seal ring boundary buffer area, adjacent seal ring wall fin structure, and adjacent chip planar region shown in FIGS. 2A and 2B according to an example embodiment of the present disclosure.

FIG. 3 is a cross sectional view of an IC structure (Embodiment 3) including a finFET region, and an interconnected HV left planar region including a planer region to fin region buffer boundary buffer area according to an example embodiment of the present disclosure.

FIG. 4 is a diagram of a semiconductor chip layout illustrating an IC layout arrangement according to an example embodiment of the present disclosure, the IC layout including one or boundary buffer areas.

FIG. 5 illustrates a method of forming an IC including a finFET region, an interconnected HV left planar region including a left planer region to fin region boundary buffer area, and an interconnected L/MV right planar region including a right planar region buffer boundary area according to an example embodiment of the present disclosure.

FIGS. 6A-6E illustrates various stages in the formation of an IC (Embodiment 5) including a finFET region, an interconnected HV left planar region including a left planer region to fin region boundary buffer area, and an interconnected L/MV right planar region including a right planar region buffer boundary area according to an example embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “intermediate,” or “intermediate step” as used herein, refers to a step, platform, structure or surface that is at a height higher than a connected or adjacent surface on a first end of the intermediate step, and at a height lower than or equal to a connected or adjacent surface at a second end of the intermediate step.

The term “recessed,” as used herein, relates to a boundary buffer area and refers to a surface or structure that has an elevation or height that is less than one or more surfaces or structures adjacent to a boundary buffer area.

The term “finFET base region,” or “fin base region” or “fin top base region,” as used herein, refers to a first end or portion of a fin, where the fin extends from an adjacent shallow trench isolation (STI) material or other material to a second end, or fin top end, from the finFET base region.

The term “layer,” as used herein, may include a single layers or multiple layers.

The term “conductive feature,” as may be used herein refers to a metallization layer contact, patterned metallization layer contact, or other electrical metal contact.

The term “intermetal dielectric” (IMD) film or layer, as may be used herein, refers to a dielectric/insulation material(s) layer between two metal layers.

The term “interlayer dielectric” (ILD) layer, as may be used herein, refers to an insulating structure of material(s) placed between two conductive layers.

In general, some embodiments disclosed herein relate to semiconductor devices employing and/or formed with one or more fin field-effect transistors (finFETs) therein. A finFET is referred to by this name because a channel between the source and drain regions of the field-effect transistor (FET) generally takes the form of a three-dimensional (3D) vertical wall or “fin” built on and/or rising from the semiconductor wafer. Accordingly, the FinFET is a type of 3D transistor. The fin serves as the transistor channel, and the gate generally contacts the top and sides of the fin. Typically, finFET devices have significantly faster switching times and higher current density compared to planar transistor devices.

This disclosure, and the example embodiments described herein, relate to optimization of IC structure topography for employing various fabrication processes used for the manufacturing of ICs, thereby enlarging the process window associated with these semiconductor manufacturing processes and reducing device defects during the manufacturing process. Generally, according to example embodiments, applicable fields include, but are not limited to, high/medium/low voltage (HV) integrated process, e.g. integrated processes for interconnecting LV (<3.3V), MV (3.3V˜12V), and HV (>12V) IC regions and manufacturing processes of the LV, MV and HV regions, integrated processes for interconnecting LV (<3.3V), and HV (>20V) IC regions and manufacturing processes, and, generally, integrated processes for interconnecting IC Planar regions with adjacent fin regions manufactured with finFET processes.

According to one example manufacturing process, some conventional static random access memory (SRAM) ICs suffer from manufacturing yield losses due to defective dummy polysilicon (“dummy poly”) gates associated with processes involved with the manufacturing of the IC, specifically the 16HV isolation ring/structure. By transmission electron microscopy (TEM) analysis, it has been observed that the step height between the HV planar region to the finFET LV regions of these SRAM devices is causing a relatively narrow process window, since the LV finFET base region, i.e., shallow trench isolation (STI) region adjacent to the finFET fin is much lower in height than the HV planar region height because the finFET fin is recessed below the HV planar region.

This disclosure and example embodiments provided here, provide solutions to improve the yield associated with the manufacturing of ICs including adjacent HV and LV regions as previously described, but is also applicable to other interconnecting semiconductor structures that include a planar region interconnected to an adjacent fin type region, such as a LV region, or any region including fins, whether active or not, such as, but not limited to, seal rings including a fin structure that are adjacent to a n IC planar region, HV, MV, LV region, or other semiconductor structures where the fin base region height is less than the adjacent or adjoining planar region height, etc. The example embodiments described herein, add a planar region, or boundary buffer area, which includes a recessed or buffer area in the fin to planar boundary region to minimize a step height slope from the fin base regions to the upper or top surface of the interconnected, relatively higher, HV/MV or other planar region for enlarging the manufacturing process window, relative to the manufacturing process window associated with IV fabrication without the disclosed boundary buffer areas. In other words, the boundary buffer area intermediate step located between the HV or higher HV planar region and the LV finFET region, according to this example, provides a reduced gradient from the base region of the finFET to the boundary buffer area step, relative to the gradient of a transition from the finFET base region to the higher interconnected planar region without the use of a boundary buffer area as disclosed. Thereby, the boundary buffer area disclosed herein results in less device defects associated with or resulting from subsequent processing associated with the manufacturing of the IC, such as forming and planarization of dielectric layers, e.g., interlayer dielectric (ILD) layers. Stated another way, the reduction in slope between adjoining and adjacent planar and fin material fill areas enables a relatively smoother surface to accommodate material fill or forming processes.

Furthermore, the disclosed structures, and methods of forming the same, according to some embodiments, use existing planar regions of currently manufactured devices and existing processes to manufacture the currently manufactured devices. Consequently, the boundary buffer area structurers and methods disclosed, according to some embodiments, which reduces the slope of planar to fin boundary area topography by using existing IC areas and manufacturing processes does not add additional fabrication costs, relative to fabrication costs associated with similar devices without the disclosed boundary buffer area.

Another example of current semiconductor structures and associated narrow process windows, includes fin LV device regions and planar MV device regions was covered by planar isolation rings to make each device isolation well. Here, the step height of the isolation ring to the fin region is relatively large due to fin area requirement of being recessed to form the fin structure.

Another further example of an existing semiconductor structure and associated narrow process windows, includes a 16HV seal ring with a fin region including a fin type boundary area to an adjacent chip's empty planar area or planar isolation ring. Without the use of a boundary buffer area as disclosed herein, the seal ring/chip topography can cause a narrow process window for subsequent processing of the device and affect device yields due to a relatively large fin (seal ring) to planar (chip) step height.

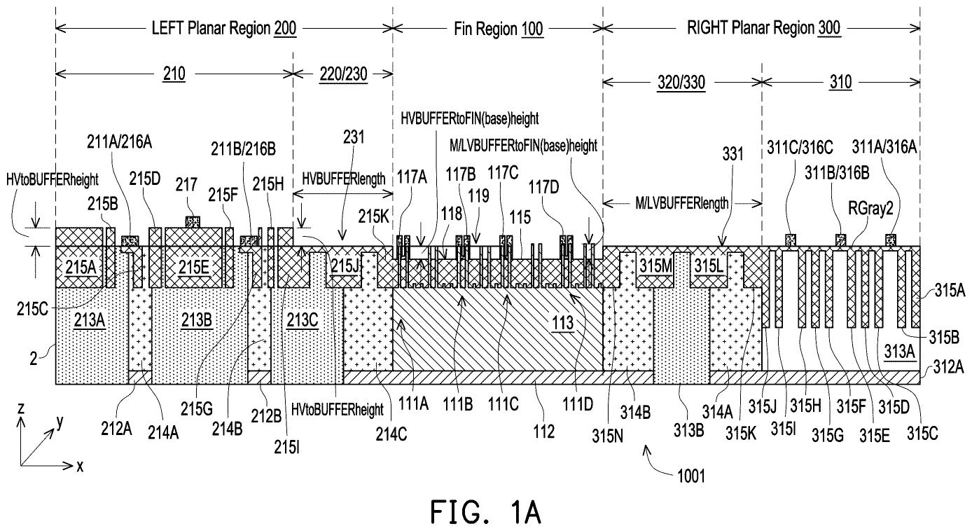

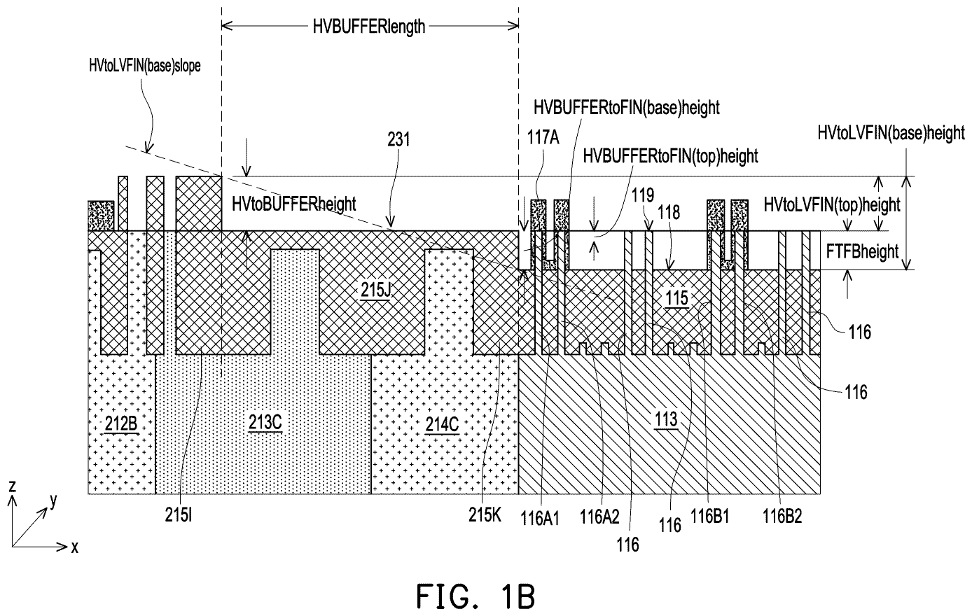

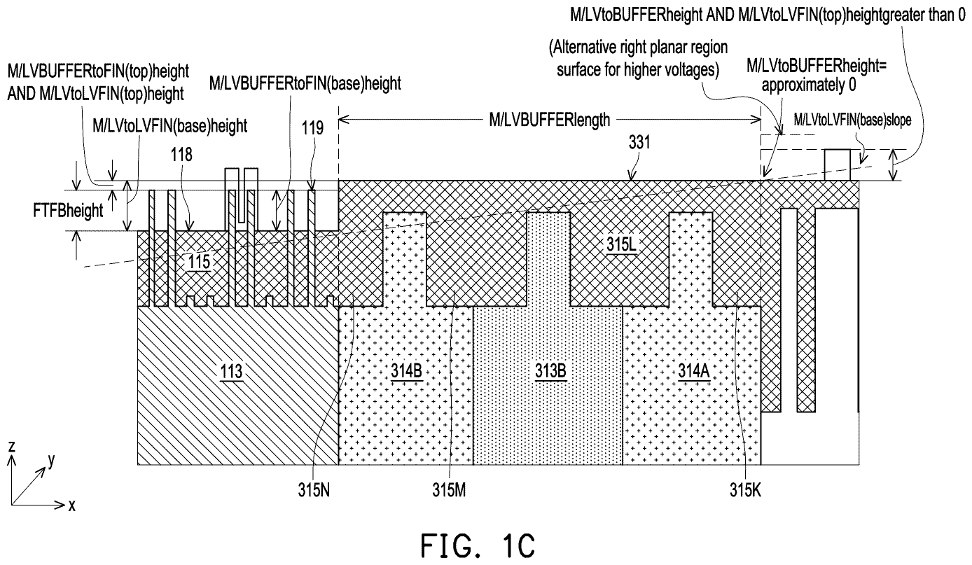

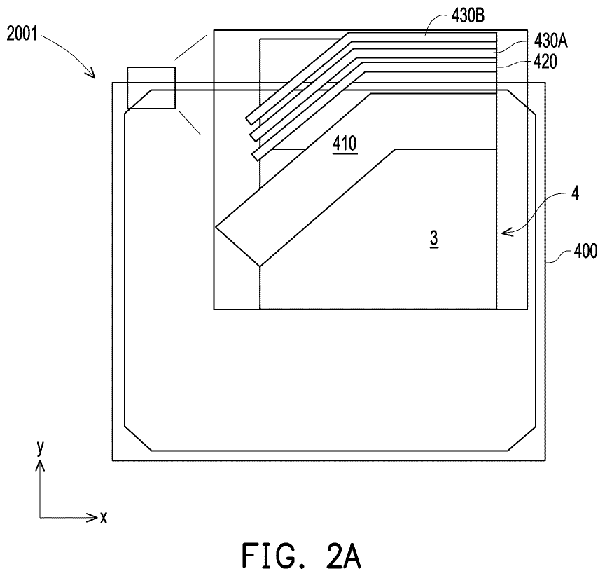

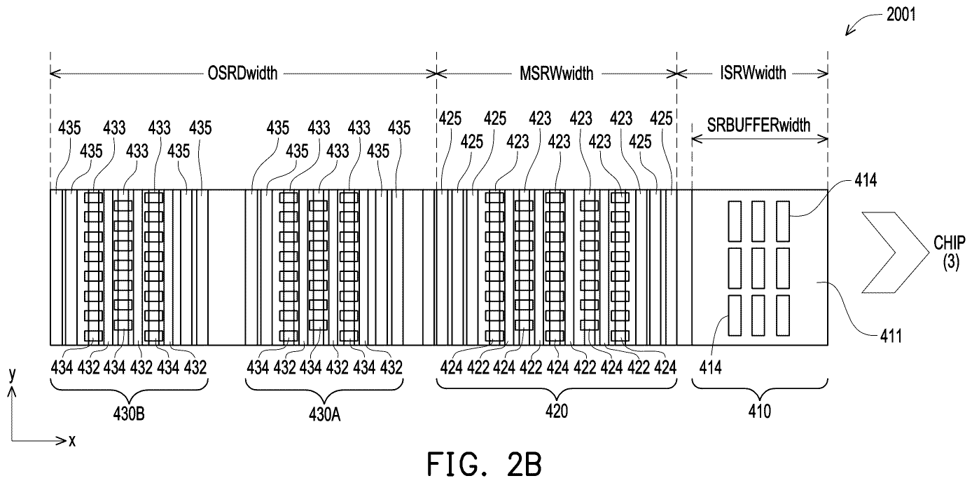

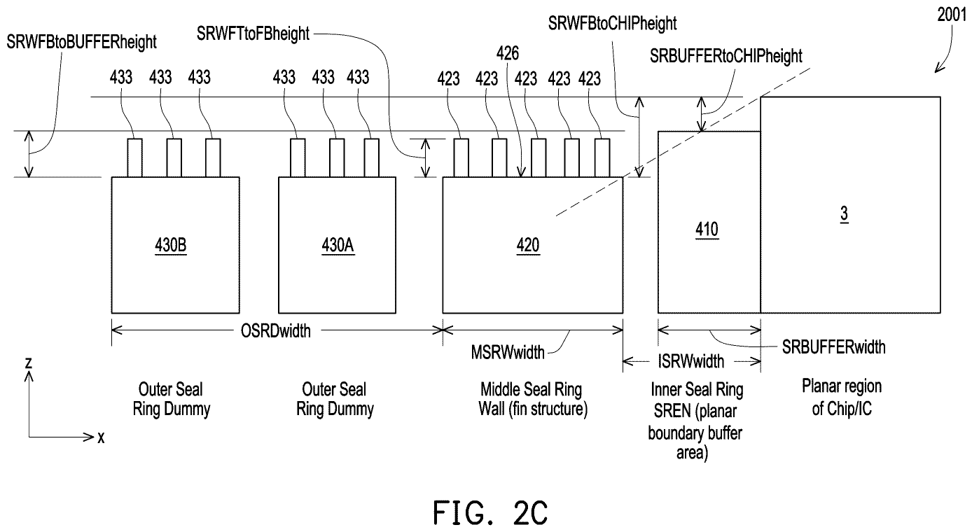

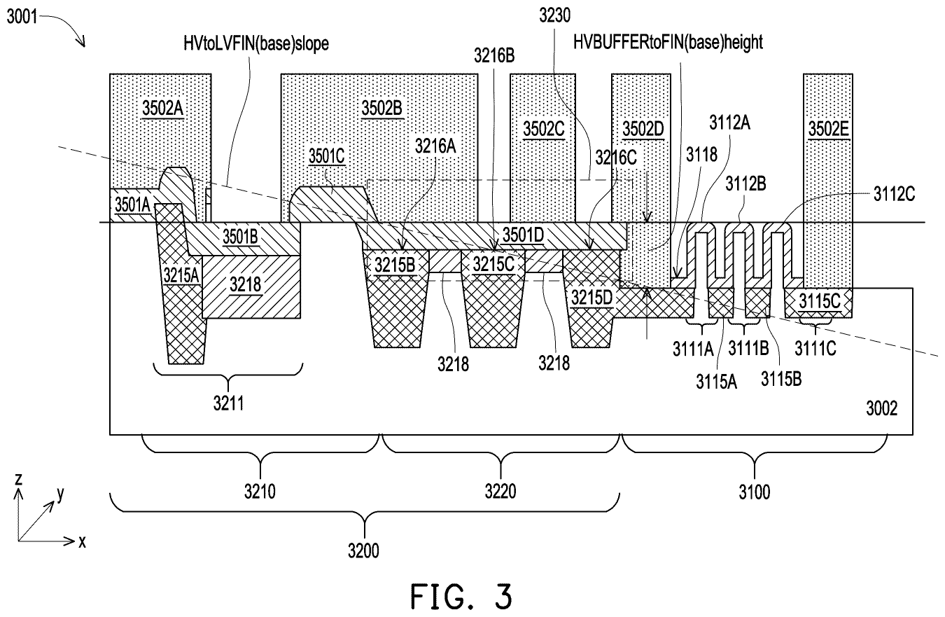

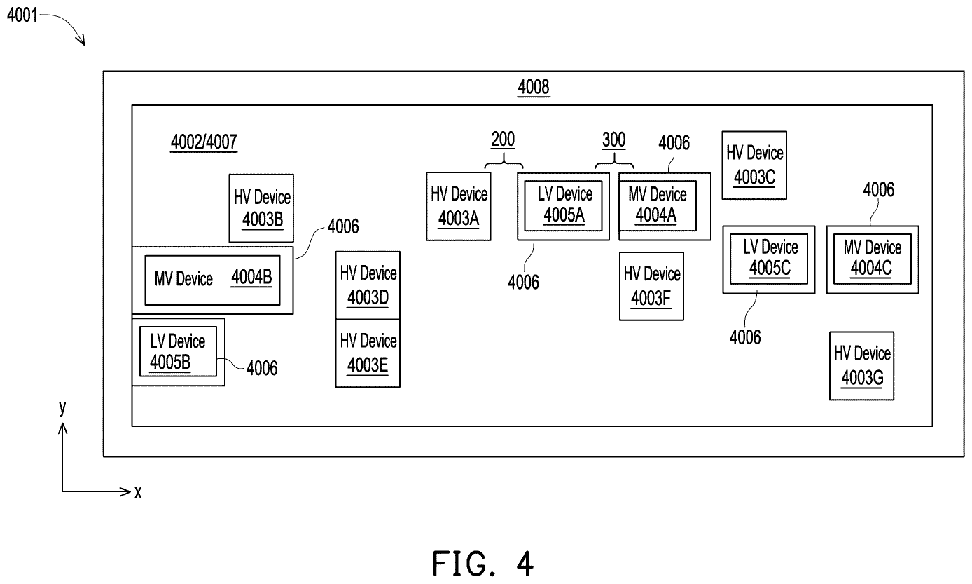

According to the example embodiments described below, wafers, ICs, semiconductor devices or structures, and methods of manufacturing the same, include one or more boundary buffer areas having an intermediate step and/or recessed planar area to minimize the step height slope of the fin to planar area transition, planar area to fin transition. According to the example embodiments described below, Embodiment 1 includes the use of a boundary buffer area formed within an isolation ring structure, which isolates a a) HV planar region boundary buffer area, interconnected to a logic or LV finFET region, b) a MV/LV planar region boundary buffer area, interconnected to the logic or LV finFET region, Embodiment 2 includes the use of a boundary buffer area formed within a seal ring enhanced zone (SREZ) which is adjacent to or connected to a chip HV or MV/LV planar region, Embodiment 3 includes the use of a boundary buffer area formed within an isolation ring structure, the isolation structure including STI trenches which extend deeper than the LV finFET STI trenches to reduce the step height from the finFET base region to the adjacent HV planar region, and Embodiment 4 which includes a chip layout that includes one or more of the boundary buffer areas of Embodiment 1 1001 (see FIGS. 1A-1C), Embodiment 2 2001 (see FIGS. 2A-2C) and Embodiment 3 3001 (see FIG. 3). Embodiment 4 4001 (see FIG. 4) provides an IV chip layout which may include one or more of Embodiments 1001, 2001 and 3001.

According to some example embodiments, a boundary buffer area is formed with an intermediate step or recess to make the step height from a higher Metal-Oxide-Semiconductor (MOS)) Silicon HV/MV/LV planar region to a lower MOS LV logic Fin region less than 60 nm.

According to some example embodiments, a boundary buffer area is formed with an intermediate step or recess to make the step height from a seal ring fin area (base region) to a seal ring planar area, the seal ring planar area, i.e. boundary buffer area, adjacent to a chip planar region that is higher than the seal buffer boundary area planar area, where the step height to the higher chip planar region planar region is less than 60 nm. According to this embodiment, the seal ring fin region fabrication process is a fin area formation process associated with the chip FinFET fabrication process where the seal ring covers the boundary buffer area. Since the original seal ring is a fin region and the chip area which contacts the seal ring is a planar area, the SREZ area or region of the seal ring is modified from a fin type to a planar type topology, thereby reducing the step height of the boundary of the seal ring to chip using an existing integrated method of manufacturing the IC. Because the seal ring does not require electric operation, it does not have an isolation ring between the chip to seal ring boundary buffer area.

According to some example embodiments, a boundary buffer area is formed with an intermediate step or recess to make the step height without using an isolation ring or seal ring, where an additional area or region of an IC is added to accommodate a boundary buffer area as disclosed.

According to some example embodiments, the LV fin region is for use as a logic circuit providing LV voltage operation for high speed, low power consumption or SRAM functions, and the planar region, interconnected with the LV logic circuit, includes MV and HV devices. According to some example embodiments, the HV devices are used for driving and controlling the LV logic circuit finFET transistors, thereby controlling the turn on/turn off functions of the transistors. MV devices are used for driving and controlling the transistor source to control the color and/brightness by voltage bias, or driving and controlling a digital to analog converter (DAC) function for signal transmission.

According to another example embodiment, an existing IC layout includes a step height or offset in height from the top of fin to a fin base, i.e., STI, of 40 nm, the step height from the adjacent and interconnected planar HV/MV region to the fin base region STI is around 30 nm. According to this example embodiment, due to some restrictions on the planar processes for fabrication of this IC, a total 70 nm step height from the HV/MV planar region to the LV fin type base region may not be desired. To accommodate the planar process, a boundary buffer area is formed using the existing structure and available area of this IC to implement a planar to fin base region transition height, i.e., step, of less than 70 nm, or less than 60 nm, or less than 50 nm, and so on.

According to some example embodiments, the use of a boundary buffer area produces a planar boundary area height near or equal to the height of the fin tops of the LV fin region. In this case the a 40 nm step height between the boundary buffer planar area to the fin STI (40 nm), and approximately 30 nm of step height between the planar boundary buffer area to the adjacent and interconnected HV planar area results in a total of approximately 70 nm from the HV planar regions to the STI fin base regions of the LV logic circuit, which is consistent with the structural design constraints of the original IC prior to the addition of the boundary buffer area. It is to be understood that is merely one example embodiment and scenarios, and other structural design constraints or requirements associated with the structure of an IC can be accommodated by the disclosed boundary buffer areas disclosed here. Specifically, boundary buffer areas provide an intermediate step between a planar region and fin region which accommodates an original IC structure requiring a total step height from a planar region to a LV fin base region more than or less than 70 nm.

With reference to FIG. 1A, shown is a cross sectional view of an integrated circuit (IC) structure (Embodiment 1) 1001 including a finFET region 100, an interconnected high voltage (HV) left planar region 200 including a left planer region to fin region buffer boundary area 230 and an interconnected low/medium voltage (L/MV) right planar region 300 including a right planar region boundary buffer area 330 according to an example embodiment of the present disclosure.

As shown, the example embodiment is an IC including the following:
a semiconductor substrate 2 having deep n-wells (DNW) 112, 212A, 212B and 312A, and a core well 113 formed thereon;
a fin region 100 formed on the core well 113, the fin region having a 1st finFET transistor structure 111A, a 2nd finFET transistor structure 111B, a 3rd finFET transistor structure 111C and a 4th finFET transistor structure 111D, and shallow trench isolation (STI) regions 115 formed adjacent each of the finFET transistor fins (e.g. see FIG. 1B: fins 116A1, 116A2, 116B1 and 116B2). Each of the fins have formed thereon polysilicon gates 117A, 117B, 117C and 117D;
a 1st planar region 200 having a HV/MV region 210, the HV/MV region 210 having formed thereon DNWs 212A and 212B, and formed thereon 1st (MOS) HV transistor device 211A and HV MOS gate 216A, 2nd (MOS) HV transistor device 211B and HV MOS gate 216B. Also formed in the HV planar region 200 are planar HV P-wells 213A, 213B, and 213C, and planar HV N-wells 214A, 214B and 214C. STIs 215A, 215B, 215C, 215D, 215E, 215F, 215G, 215H, 215I, 215J and 215K are formed to provide isolation of the various depicted semiconductor regions for operation of the HV planar region as well as dummy poly gate 217; and
a 2^{nd} planar region 300 having a M/LV region 310, the M/LV region 310 formed on DNW 312A and formed thereon 1st M/LV transistor device 311A and M/LV metal gate 316A, 2nd M/LV transistor device 311B and M/LV metal gate 316B, and 3rd M/LV transistor device 311C and M/LV metal gate 316C. Also formed in the M/LV planar region 300 are planar M/LV P-well 313B, planar M/LV N-wells 314A and 314B, and M/LV region planar well 313A. STIs 315A, 315B, 315C, 315D, 315E, 315F, 315G, 315H, 315I, 315J, 315K, 315L, 315L, 315M and 315N are formed to provide isolation of the various depicted semiconductor regions for operation of the M/LV planar region.

The 1st planar region 200 further includes an isolation (ring) structure 220 having a left planer region to fin region boundary buffer area 230, and a left planer region to fin region boundary buffer area top surface 231.

The 2nd planar region 300 further includes an isolation (ring) structure 320 having a right planer region to fin region boundary buffer area 330, and a right planer region to fin region boundary buffer area top surface 331, where the isolation (ring) structure extends from STI 315N to planar M/LV P-well 313B. The complete isolation (ring) structure 220 and 320 encircles the LV logic region 100 structure.

According to an example embodiment, the IC 1001 is formed on a wafer made of a semiconducting material, where the integrated interconnect structure 1001 or integrated circuit (IC) is built or formed thereon by conventional semiconductor fabrication techniques, including but not limited to photolithographic techniques such as applying a pattern/structure in a given layer by applying a photoresist layer, patterning the photoresist layer, developing the photoresist layer, and then etching, followed by planarizing and cleaning. While the specific semiconductor fabrication processes required to form the IC 1001 shown are not the focus of this disclosure, for completeness a general description of the semiconductor fabrication processes follows.

The semiconductor substrate 2 materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

Dielectric structures can be made from any suitable combination of dielectric materials. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material, such as metal vias 240A and 240B, discussed herein may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

As shown in FIG. 1A, as well as FIGS. 1B, the HV planar region 210 is the highest position in the IC chip/semiconductor structure 1001, and the M/LV planar region 310 highest position is relatively the same as the vertical height of the fin region 100. Therefore, the boundary buffer area 230 implemented in the 1^{st} or left planar region 200 may have an intermediate or recessed step height different from the boundary buffer area 330 implemented in the 2nd or right planar region 300. For example, according to some embodiments, the step height from the HV planar region 210 to the fin base regions 118 is less than 70 nm, while the step height from the M/L planar region 310 to the fin base regions 118 is less than 60 nm. While FIG. 1A, and others show a M/LV planar region 310 which is relatively the same height as the fin region 100, the M/LV planar region 310 may extend further vertically (z direction), depending on the voltage platform accommodated by the M/L planar region 310. However, unless the left planar region 200 is a HV planar region, the M/LV planar region 310 will have a vertical height less than the HV planar region 210 and greater than or equal to the vertical height of the fin region 100.

Further, the HV planar region 200 shown in FIG. 1A includes an isolation ring 220 (nearby fin area) which is fabricated or modified to include boundary buffer area 230, and the M/LV planar region 300 includes an isolation ring 320, which is fabricated or modified to include boundary buffer area 330, The example structure shown in FIG. 1A is a general structure used for display driver IC(s) that mix LV, MV, and HV devices. The SRAM of a DDIC is part of the FinFET region 100 with isolation rings 220 and 320, and the LV, MV, HV devices are adjacent the isolation rings 220 and 320 of the SRAM. Other LV functions associated with the M/LV region 300 may include, but are limited to, a timing controller (TCON). The SRAM or fin region 100 is composed of FinFET bit cells and it needs to be surrounded by the isolation rings (planar area) 220 and 330 to block MV or HV voltage nearby the fin region 100 or SRAM area.

With reference to FIG. 1B, along with FIG. 1A, shown is a detailed cross sectional view of the left planar region boundary buffer area of the IC structure (Embodiment 1) shown in FIG. 1A according to an example embodiment of the present disclosure.

According to one example embodiment, the following table provides various dimensional labels as referenced in the figures, and example dimensional ranges.

| Description of Dimensional Label | |
|---|---|
| Value | Dimensional Label |
| HV Planar Region to Boundary | HVtoBUFFERheight is from about 25 nm to about |
| Buffer Area Recess/Intermediate | 35 nm |
| Step height | |
| HV Boundary Buffer Area | HVBUFFERtoFIN(base)height is from about 35 nm |
| (intermediate step) to Fin Region | to about 45 nm |
| (base) height | |
| HV Boundary Buffer Area | HVBUFFERtoFIN(top)height is less than 60 nm |
| (Intermediate Step) to Fin Region | |
| (Top) Height | |
| Fin Top to Fin Base (STI) Height | FTFBheight is from about 35 nm to about 45 nm |
| HV Boundary Buffer Area Length | HVBUFFERlength is from about 2.5 um to about |
| | 5.5 um |
| HV Planar Region to LV Fin | HVtoLVFIN(base) slope is less than 1:80 |
| Region Base Slope | |
| HV Planar Region to Fin Top | HVtoLVFIN(top)height is less than 60 nm |
| HV Planar Region to LV Fin Base | HVtoLVFIN(base)height is equal to less than about |
| | 70 nm, or FTFBheight + HVtoLVFIN(top)height is |
| | equal to less than about 70 nm. |
| ML/LV Planar Region to Boundary | M/LVtoBUFFERheight is from about 0 to about |
| Buffer Area Recess/Intermediate | 35 nm |
| Step Height | |
| ML/LV Boundary Buffer Area | MLVBUFFERtoFINBASEheight is from about 35 nm |
| (Intermediate Step) to Fin Region | to about 45 nm |
| Height | |
| M/LV Boundary Buffer Area | M/LVBUFFERtoFIN(top)height is less than 60 nm |
| (Intermediate Step) to Fin Region | |
| (Top) Height | |
| M/LV Planar Region to LV Fin | M/LVtoLVFIN(base) slope is less than 1:80 |
| Region Base Slope | |
| M/LV Boundary Buffer Area | M/LVBUFFERlength is from about 2.5 um to about |
| Length | 5.5 um |
| M/LV Planar Region to Fin Top | M/LVtoLVFIN(top)height is less than 60 nm |
| M/LV Planar Region to LV Fin | M/LVtoLVFIN(base) height is less than 70 nm; or |
| Base | FTFBheight + M/LVtoLVFIN(top)height is less than |
| | 70 nm. |

According to one illustrative example, if the step height of the fin top 119 to the fin base region 115 (FTFBheight) in the LV fin region 100 is X nm, with the implementation of a boundary buffer area 230 as disclosed, both the HVtoBUFFERheight and FTFBheight will be less than or equal to X+10 nm. If the length of the boundary buffer area HVBUFFER length is Y nm, X+10/Y is less than or equal to 1/80. i.e., 1:80, (HVtoLVFIN (base) slope).

With reference to FIG. 1C, shown is a detailed cross sectional view of the right planar region boundary buffer area 330 of the integrated circuit IC structure (Embodiment 1) shown in FIG. 1A, including depicting the slope of the boundary buffer area relative to the height of a M/LV planar region 310 and a LV finFET region 100 (Embodiment 1) according to an example embodiment of the present disclosure.

As previously discussed herein, the function of the HV boundary buffer area 230 and M/LV boundary buffer area 330 is to abate or reduce the slope of the planar region to fin region boundary. The required length of the boundary buffer areas is dependent on the fin base region to planar region step height (HVBUFFERtoFIN(base) height and MLVBUFFERtoFINBASEheight). If the length of the boundary buffer area is too short, the transitional height, or slope, from the fin region base 215A to the boundary buffer area planar top surface could be too steep to accommodate some subsequent processing, such as planarization, within a desired process window. The slope is defined as the total step height from the LV fin region base 118 (STI) to the HV planar region 210 top surface, and from the LV fin region base (STI) to the M/LV planar region 310 top surface, as shown in FIGS. 1B and 1C, divided by the length of the boundary buffer areas, HVBUFFERlength and M/LBUFFERlength, respectively. According to an example IC embodiment, a boundary buffer area length resulting in a boundary buffer slope of <1:80 is desired.

With reference to FIG. 2A shown is a top view of a die portion of a wafer including an IC structure 3 including a chip/IC/device planar region adjacent to a seal ring 400 encircling the chip 3, the seal ring 400 including an outer seal ring dummy 430A and 430B, a fin type middle seal ring wall 420 and a planar inner seal region 410, i.e. seal ring enhanced zone (SREN), the planar inner seal region 410 including a boundary buffer area according to an example embodiment of the present disclosure (Embodiment 2), the boundary buffer area abating a step height from the seal ring wall fins 423 (See FIGS. 2B and 2C) to a planar region adjacent the planar inner seal boundary buffer area of the chip. FIG. 2B shows a detailed top view of the die portion of the wafer including an integrated circuit (IC) structure as shown in FIG. 2A, this figure showing details of the outer seal ring dummy structure 430A and 430B, the middle seal ring wall 420 fin structure, and the inner seal ring 410 boundary buffer area structure. FIG. 2C shows a cross sectional view of the seal ring boundary buffer area 410, adjacent seal ring wall 420 fin structure, and adjacent chip 3 planar region shown in FIGS. 2A and 2B.

Embodiment 2 IC structure includes a seal ring 400 which encircles an IC chip 3, for example an IC chip 3 including one or both of Embodiment 1 1001 and Embodiment 2 2001, previously described, however not limited to these embodiments. The seal ring 400 has an inner seal ring boundary buffer area 410 including a planar layer 411 and dummy polysilicon gates 414; a middle intermediate seal ring wall (fin structure) 420 and dummy outer seal rings 430A and 430B. The middle seal ring wall 420 has a plurality of fins 423 formed therein using mandrels 422 and dummy polysilicon gates 424, and the outer dummy ring has a plurality of fins 433 formed therein using mandrels 432 and dummy polysilicon gates 434. Outer dummy seal rings 430A and 430B include metal layer (active layer) 435 formed therein, and middle seal ring wall 420 includes metal layer (active layer) 425 formed therein.

Distinguishable from the boundary buffer area integration shown in FIGS. 1A-1C, the seal ring integration of a boundary buffer area is directed to forming an intermediate step or transition from the seal ring wall fin base region 426 to a planar region or surface on a chip 3 encircled by the seal ring 400. The seal ring intermediate step provides an abatement of the gradient, i.e., slope, from the seal ring fin base region 426 to the adjacent chip planar surface 3, which could be a HV planar region, MV planar region, LV planar region and/or a planar region that is a portion of a HV/MV/LV isolation structure.

According to an example Embodiment 2001, Embodiment 2001 includes a boundary buffer area implemented by modifying an existing seal ring with a planar recess to abate the step height from the seal ring to an adjacent planar chip surface. The seal ring structure 400 is modified from a full fin area to include a fin+planar (SREZ) inner seal 410 that reduces or shortens the boundary step height from the seal ring to the adjacent chip, the SREZ being the reserved space between the chip 3 and seal ring wall 420 prevents die saw stress from damaging the chip.

According to an example embodiment, the seal ring dummy 430A and 430B length is from about 3.6 to about 7.2 μm, also referred to as a “scribe line dummy bar.” More particularly, the seal ring dummy 430A and 430B length is about 7.2 μm according to an example embodiment. In practice, the seal ring dummy 430A and 430B length is dependent on the die saw capacity. In the chip 2 area, according to an example embodiment, the mandrel width/space is about 48 nm/48 nm, however the seal ring is designed about 140 nm/140 nm. The mandrel used for the seal ring fin pattern formation can also be used during the formation of other fins of the IC, e.g., fin area transistor fins.

According to an example embodiment, the seal ring wall length is from about 2.7 μm to about 5.4 μm, depending on the seal ring wall's resistance and ability to stress and moisture. More particularly, according to some embodiments, the seal ring wall 420 length is about 5.4 μm.

The boundary buffer area or inner seal 410 has a planar area width from about 2.7 μm to about 6 μm. More particularly, according to some embodiments, the boundary buffer area width is about 2.46 μm. According to an example embodiment, the seal ring 400 and adjacent planar chip regions use the same fabrication processes with the chip 3 being fabricated/processed while the seal ring is being fabricated/processed. Example seal ring materials include, but are not limited to, silicon, oxide, metal, passivation materials, etc.

According to an example embodiment, the following table provides various dimensional labels and example dimensional ranges.

| Description of Dimensional Label | |
|---|---|
| Value | Dimensional Label |
| Seal Ring Wall Fin/Inner Seal Fin | SRWFBtoBUFFERheight is from about 35 nm to |
| Portion STI to Boundary Buffer Area | 45 nm |
| (Planar STI) Recess/Intermediate | |
| Step Height | |
| Seal Ring Boundary Buffer Area | SRBUFFERtoCHIPheight is less than 60 nm |
| (Planar Intermediate Step) to Device | |
| Planar Region Step Height | |
| Seal Ring Wall Fin Top to Fin | SRWFTtoFBheight is from about 35 nm to 45 nm |
| Base/STI Height | |
| Seal Ring Boundary Buffer Area | SRBUFFERwidth is from about 2.7 um to about 6 |
| Length | um |
| Middle Seal Ring Wall Fin Base to | SRWFBtoCHIPslope is less than 1:80 |
| Chip Planar Region Slope | |
| Outer Seal Ring Dummy Width | OSRDwidth is from about 3.6 um to about 7.2 um |
| Middle Seal Ring Wall Width | MSRWwidth is from about 2.7 to about 5.4 um |
| Inner Seal Ring Wall Width | ISRWwidth is from about 2.7 um to about 6 um |

With reference to FIG. 3, shown is a cross sectional view of an IC structure (Embodiment 3) 3001 including a finFET region 3100, and an interconnected HV left planar region 3200 including a planer region to fin region boundary buffer area 3220 according to an example embodiment of the present disclosure.

As shown, the example embodiment is an IC including the following:
a semiconductor substrate 3002 2 having a HV planar region 3211, a LV fin region 3100 and an isolation structure 3220, i.e., isolation ring formed therein. Further formed are STI regions 3215A, 3215B, and 3215C and 3215D within the semiconductor substrate 3002. The fin region 3100 has a 1st finFET transistor structure 3111A, a 2nd finFET transistor structure 3111B, and a 3rd finFET transistor structure 3111C. where the STI regions 3115A, 3115B, and 3115C are formed adjacent each of the finFET transistor fins 3112A, 3112B and 3112C Each of the fins have formed thereon polysilicon gates (not shown); and
a HV planar region 3200 having a HV region 3210, the HV/MV region 3210 having formed thereon HV STIs 3215A, 3215B, 3215C and 3215D, and formed thereon a (MOS) HV transistor device 3211 and HV MOS gate/GOX (gate oxide) 3218. Also formed in the HV planar region HTO (high temperature dielectric) regions 3501A, 3501B, 3501C and 3501D to provide isolation of the various depicted semiconductor regions for operation of the HV planar region.

ILD0 layer/regions 3502A, 3502B, 3502C, 3502D and 3502F are formed on the HV and LV device shown are used for planarization processing.

Similar to the boundary buffer areas previously described with reference to FIGS. 1A-C, the IC includes a boundary buffer area 3230 that includes a HVBUFFERtoFIN(base)height that is about 35 nm to about 45 nm, and a HVtoLVFIN(base) slope less than 1:80.

Distinguishable from the boundary buffer area integration shown in FIGS. 1A-1C, the Embodiment 3 integration of a boundary buffer area 3230 is directed to forming an intermediate step or transition from the HV planar region 3210 to the LV fin base region 3118, wherein the IC structure includes an isolation ring 3220 or structure that is formed with the mesas of STIs 3215A, 3215B and 3215C, and with mesa tops 3216A, 3216B and 3216C, respectively, at a height lower than the LV fin tops.

With reference to FIG. 4, shown is diagram of a semiconductor chip layout 4002 illustrating an IC layout arrangement according to an example embodiment (Embodiment 4) 4002 of the present disclosure, the IC layout including a HV planar region 200 and a MV planar region 300 as previously described. As shown, Embodiment 4 4001 further includes HD devices 4003A, 4003B, 4003C, 4003D, 4003E, 4003F and 4003G; MV devices 4004A, 4004B and 4004C; and LV devices 4005A, 4005B and 4005C. Dummy HV isolation rings 4006 encircle each of the LV and MV devices to insulate the LD and MD devices from the operation of the HD devices and HV isolation ring 4007 is formed to cover areas of the chip 4002 not used by the LV, MV and HV devices. A seal ring 4008 prevents die saw stress from damaging the chip 4002.

According to an example embodiment and to further aid in the understanding of the disclosed boundary buffer area structures disclosed herein, a boundary buffer area 230 (not shown) is integrated into the HV planar region 200 of HV device 4003A, the boundary buffer area 230 (not shown) abating and/or providing an intermediate step from the HV device 4003A planar region to a fin base region of the LV device 4005A as previously described with reference to FIGS. 1A-1C and/or FIG. 3. In addition, a boundary buffer area 330 (not shown) is integrated into the MV planar region 300 of MV device 4004A, the boundary buffer area 330 (not shown) abating and/or providing an intermediate step from the MV device 4004A planar region to a fin base region of the LV device 4005A as previously described with reference to FIGS. 1A-1C and/or FIG. 3. Furthermore, seal ring 4008 can include a seal ring structure including an inner seal ring having a boundary buffer area 410 (not shown) a previously described with reference to FIGS. 2A-2C, the seal ring boundary buffer area providing an intermediate step from the seal ring 4008 to a planar surface of the chip 4002/isolation ring 4007 and/or dummy isolation rings 4006 as previously described.

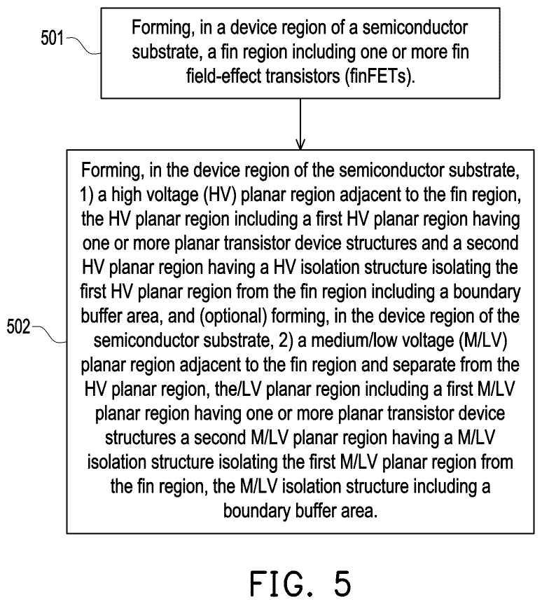

With reference to FIG. 5, illustrated are various stages in the formation of an IC including a finFET region, an interconnected HV left planar region including a left planer region to fin region boundary buffer area, and an interconnected L/MV right planar region including a right planar region boundary buffer area according to an example embodiment of the present disclosure.

At step 501, the method forms, in a device region of a semiconductor substrate, a fin region including one or more fin field-effect transistors (finFETs), each device region finFET including one or more fins formed to have a fin top at a first height from a finFET base region adjacent to the finFET fin and a gate formed to wrap around one or more of the one or more fin tops.

At step 502, the method forms, in the device region of the semiconductor substrate,
1) a high voltage (HV) planar region adjacent to the fin region, the HV planar region including a first HV planar region having one or more planar transistor device structures formed at a second height from the finFET base region, the second height greater than the first height, and a second HV planar region having a HV isolation structure isolating the first HV planar region from the fin region, the HV isolation structure including a boundary buffer area having an intermediate step at a third height from the finFET base region that is equal to or greater than the first height and less than the second height; and
2) (optional) a medium/low voltage (M/LV) planar region adjacent to the fin region and separate from the HV planar region, the/LV planar region including a first M/LV planar region having one or more planar transistor device structures formed at a second height from the finFET base region, the second height greater than the first height, and a second M/LV planar region having a M/LV isolation structure isolating the first M/LV planar region from the fin region, the M/LV isolation structure including a boundary buffer area having an intermediate step at a third height from the finFET base region that is equal to or greater than the first height and less than the second height.

Some processes that may be used to form the IC disclosed here include chemical mechanical polishing (CMP), wet etching, photolithography to limit the area of the CMP/chemical etching. According to some example embodiments, the boundary buffer area intermediate step is formed by removing material of an existing isolation ring area encircling an IC logic LV fin area, or in the case of Embodiment 3 where the boundary buffer area is integrated with a seal ring, removing material of the seal ring within the SREZ to form a planar intermediate step between the seal ring and the IC chip adjacent planar region.

For Embodiment 1, where the IC includes a HV planar region and a M/LV planar region, a MV processing mask is used to define the boundary buffer area intermediate step/recess area in the isolation ring, and this MV processing mask is used also to define thee SREZ of the seal ring using photolithography processes. Then, the recess/step creation process is performed using a dry chemical etching process. (Fin recess formation is done subsequent to planar formation processes) The result is boundary buffer areas with a step height to the fin base regions similar to the MV planar regions, but with HV wells in these area for isolation purpose.

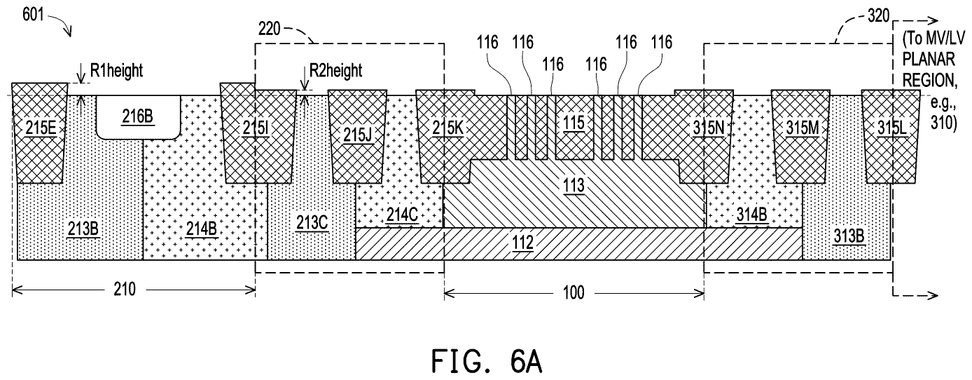

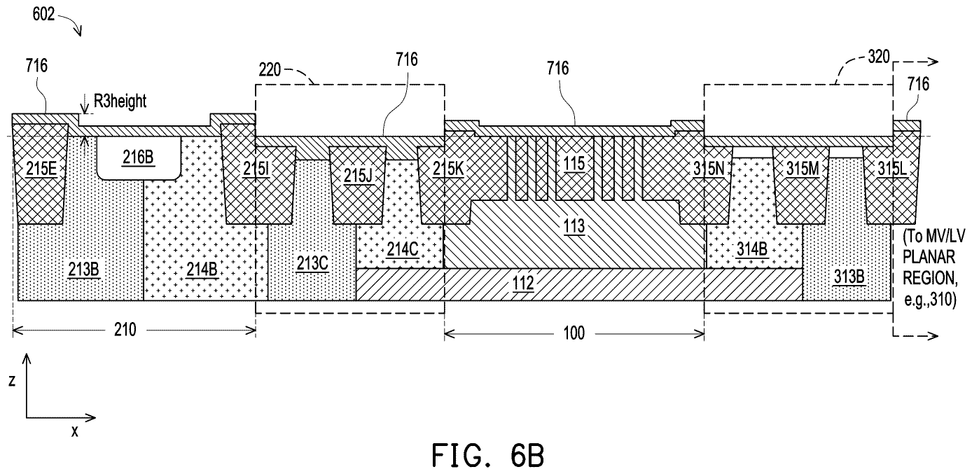

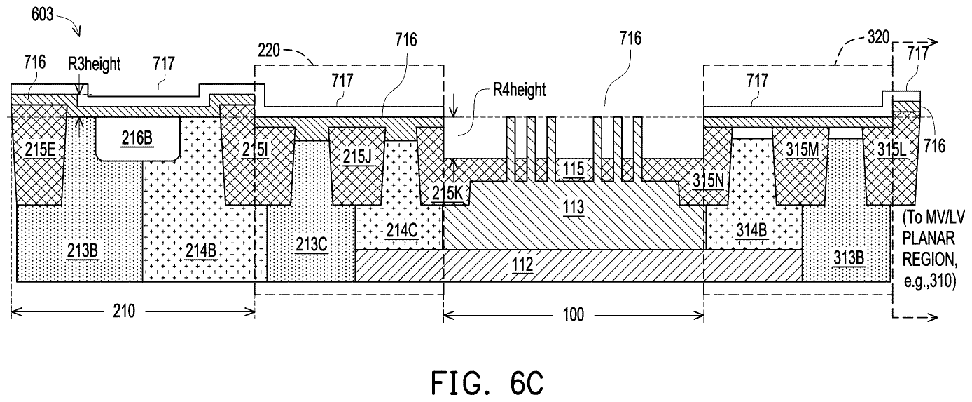

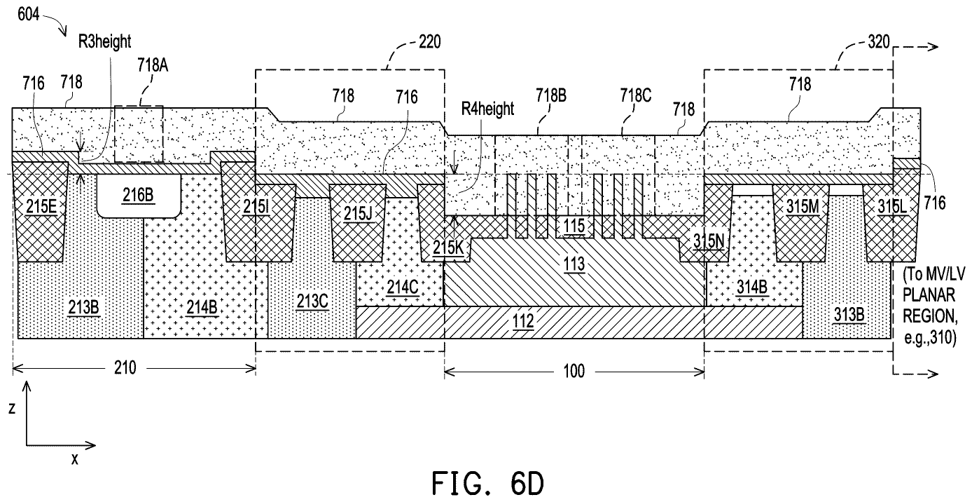

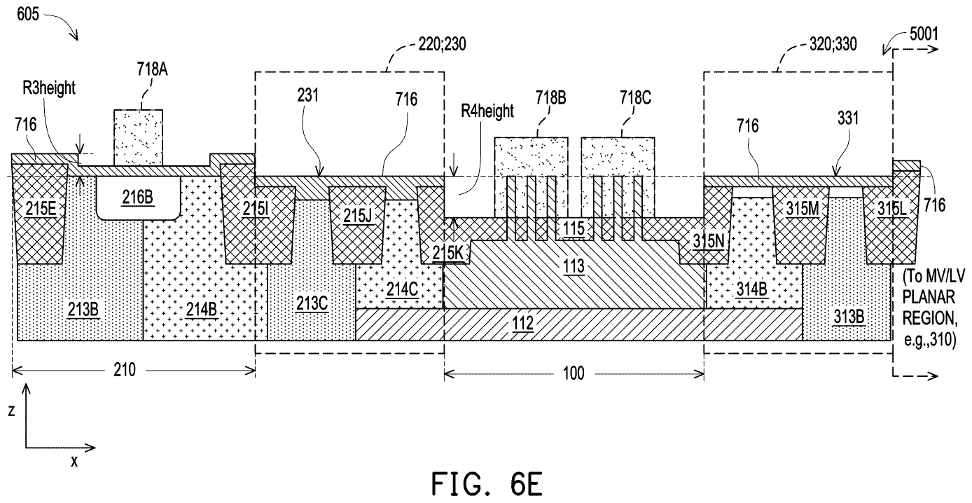

With reference to FIGS. 6A-6E, illustrated are various stages in the formation of an IC (Embodiment 5) 5001 including a finFET region, an interconnected HV left planar region including a left planer region to fin region boundary buffer area, and an interconnected L/MV right planar region including a right planar region boundary buffer area according to an example embodiment of the present disclosure.

FIG. 6A illustrates an initial stage 601 of forming a boundary buffer area as previously described with reference to FIGS. 1A-1C. where the initial partially formed IC structure state is previously formed using semiconductor fabrication photolithography processes previously described. The fin region 100, HV planar region 210 and optional M/LV planar region 310, as well as isolation rings 220 and 320, and boundary buffer areas 230 and 330 are substantially the functional equivalents of the like reference characters previously described herein with reference to FIGS. 1A-1C and are not repeated here.

As shown, at the initial stage 601 of the process, the semiconductor IC structure is previously formed to include a recessed height 1 (R1height) which is the initial recess height of HVGOX gate 216B of the HV planar region 210 to HV STI 215E, e.g., about 100 nm, prior to forming boundary buffer area 230. In addition, the semiconductor IC structure is previously formed to include a recessed height 2 (R2height), which is the initial recess height of the isolation ring planar region 220 relative to HV STI 215I, e.g., 100 nm, prior to forming boundary buffer area 230.

The processing or fabrication steps described below focus on the forming of the planar HV boundary buffer area 230 HV (See FIG. 6E) However, it is to be understood that similar processing is performed to form the M/LV boundary buffer area 330 (see FIG. 6E) concurrently as the HV boundary buffer area fabrication proceeds.

FIG. 6B illustrates stage 602 of the boundary buffer area fabrication process, including the forming of a MVGOX (Middle Voltage GOX) layer 716 on the structure of FIG. 6A, thereby covering the entire surface of the HV planar region 210 isolation ring structure 220, fin region 100, isolation ring structure 320 and M/LV planar region 310. An etching process is further performed to etch the MVGOX layer 716 to form Recessed Height 3 (R3height) which is the recess height of HVGOX gate 216B of the HV planar region 210 to HV STI 215E, e.g., about 300 nm, after etching.

FIG. 6C illustrates the next stage 603, which includes applying a hard mask 717 to MVGOX layer 716 and performing an etching process to remove some of the STI material 115 and form the recess for fins 116 (R4height), which also provides the recess height from the HV isolation ring planar region 210/boundary buffer area top surface 231, e.g., 400 nm.

FIG. 6D illustrates the next stage 604, which includes applying a polysilicon layer 718 over the entire surface of the structure shown in FIG. 6C and performing a CMP process to planarize the surface. For reference, area 718A, 718B and 718C outline the subsequently formed poly gates 718A, 718B and 718C of the next stage shown in FIG. 6E.

FIG. 6E illustrates the next stage 605, which includes performing a photolithography process to etch the CPM planarized surface of polysilicon layer 718 and form poly gates 718A, 718B and 718C. The resulting semiconductor IC structure 5001 shown includes the completed boundary buffer areas 230 and 330, formed and integrated into isolation rings 220 and 320, respectively.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed IC boundary buffer areas provide an bated step height from a fin region to an adjacent planar region, which in turn may improve a process window associated with one or more subsequent semiconductor fabrication processes.

In the following, some further embodiments are described.

In a nonlimiting illustrative embodiment, a method of manufacturing an integrated circuit (IC), the method comprising: forming, in a device region of a semiconductor substrate, a fin region including one or more fin field-effect transistors (finFETs), each device region finFET including one or more fins formed to have a fin top at a first height from a finFET base region adjacent to the finFET fin and a gate formed to wrap around one or more of the one or more fin tops; forming, in the device region of the semiconductor substrate, a high voltage (HV) planar region adjacent to the fin region, the HV planar region including a first HV planar region having one or more planar transistor device structures formed at a second height from the finFET base region, the second height greater than the first height, and a second HV planar region having a HV isolation structure isolating the first HV planar region from the fin region, the HV isolation structure including a boundary buffer area having an intermediate step at a third height from the finFET base region that is equal to or greater than the first height and less than the second height.

In another nonlimiting illustrative embodiment, an integrated circuit (IC) comprising: a semiconductor substrate; and a device region including one or more fin field-effect transistors (finFETs), each device region finFET including one or more fins formed to have a fin top at a first height from a finFET base region adjacent to the finFET fin and a gate formed to wrap around one or more of the one or more fin tops; the device region including a high voltage (HV) planar region adjacent to the fin region, the HV planar region including a first HV planar region having one or more planar transistor device structures formed at a second height from the finFET base region, the second height greater than the first height, and a second HV planar region having an isolation structure isolating the first planar region from the fin region, the isolation structure including a boundary buffer area having an intermediate step at a third height from the finFET base region that is equal to or greater than the first height and less than the second height.

In another nonlimiting illustrative embodiment, a method of manufacturing an integrated circuit (IC), the method comprising: forming, in a device region of a semiconductor substrate, a fin region including one or more fin field-effect transistors (finFETs), each device region finFET including one or more fins and a gate formed to wrap around one or more tops of the one or more fins, and a planar region adjacent to the fin region, the planar region including one or more planar semiconductor device structures; forming a seal ring region encircling the device region, the seal ring region including an inner seal ring encircling the device region and an outer seal ring encircling both the inner seal ring and the device region, the outer seal ring including a plurality of fins, each of the fins having a fin top at a first height from a fin base region adjacent to the fin, and the inner seal ring including a planar boundary buffer area adjacent to the device planar region and formed at a second height from the fin base region, the second height less than the first height.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an integrated circuit (IC), the method comprising:
forming, in a device region of a semiconductor substrate, a fin region including one or more fin field-effect transistors (finFETs), each device region finFET including one or more fins formed to have a fin top at a first height from a finFET base region adjacent to the finFET fin and a gate formed to wrap around one or more of the one or more fin tops;
forming, in the device region of the semiconductor substrate, a high voltage (HV) planar region adjacent to the fin region, the HV planar region including a first HV planar region having one or more planar transistor device structures formed at a second height from the finFET base region, the second height greater than the first height, and a second HV planar region having a HV isolation structure isolating the first HV planar region from the fin region, the HV isolation structure including a boundary buffer area having an intermediate step at a third height from the finFET base region that is equal to or greater than the first height and less than the second height.

2. The method of claim 1, wherein the boundary buffer area has a slope defined as the second height divided by a boundary buffer area length, and the slope is less than or equal to 1:80.

3. The method of claim 1, further comprising:
forming in the planar region a high voltage (HV) circuit; and
forming on the fin region a low voltage (LV) circuit operatively controlled by the HV circuit, the HV circuit operating voltage range greater than about 12 volt, and the LV circuit operating voltage greater than about 3 volts and less than about 12 volts.

4. The method of claim 1, wherein the first height is about 35 nm to about 45 nm, and the third height is from about 35 nm to about 45 nm.

5. The method of claim 1, wherein first height substantially equals the third height.

6. The method of claim 6, wherein the boundary buffer area is formed by a method comprising:
performing a photolithographic process to etch at least a portion of the isolation structure to form a recess at the third height, the recess defining the intermediate step of the boundary buffer area.

7. The method of claim 1, wherein the HV isolation structure is an isolation ring.

8. The method of claim 1, further comprising:
forming, in the device region of the semiconductor substrate, a medium/low voltage (M/LV) planar region adjacent to the fin region and separate from the HV planar region, the/LV planar region including a first M/LV planar region having one or more planar transistor device structures formed at a second height from the finFET base region, the second height greater than the first height, and a second M/LV planar region having a M/LV isolation structure isolating the first M/LV planar region from the fin region, the M/LV isolation structure including a boundary buffer area having an intermediate step at a third height from the finFET base region that is equal to or greater than the first height and less than the second height.

9. The method of claim 8, wherein the HV planar region second height is greater than the M/LV planar region second height.

10. The method of claim 8, wherein the HV planar region boundary buffer area third height is substantially equal to the M/LV planar region boundary buffer area third height.

11. An integrated circuit (IC) comprising:
a semiconductor substrate; and
a device region including one or more fin field-effect transistors (finFETs), each device region finFET including one or more fins formed to have a fin top at a first height from a finFET base region adjacent to the finFET fin and a gate formed to wrap around one or more of the one or more fin tops;
the device region including a high voltage (HV) planar region adjacent to the fin region, the HV planar region including a first HV planar region having one or more planar transistor device structures formed at a second height from the finFET base region, the second height greater than the first height, and a second HV planar region having an isolation structure isolating the first planar region from the fin region, the isolation structure including a boundary buffer area having an intermediate step at a third height from the finFET base region that is equal to or greater than the first height and less than the second height.

12. The IC of claim 11, wherein the boundary buffer area has a slope defined as the second height divided by a boundary buffer area length, and the slope is less than or equal to 1:80.

13. The IC of claim 11, wherein the first height is about 35 nm to about 45 nm, the third height is from about 35 nm to about 45 nm, and the first height substantially equals the third height.

14. The IC of claim 11, wherein the HV isolation structure is an isolation ring.

15. The IC of claim 11, further comprising;
the device region including a medium/low voltage (M/LV) planar region adjacent to the fin region and separate from the HV planar region, the M/LV planar region including a first M/LV planar region having one or more planar transistor device structures formed at a second height from the finFET base region, the second height greater than the first height, and a second M/LV planar region having a M/LV isolation structure isolating the first M/LV planar region from the fin region, the M/LV isolation structure including a boundary buffer area having an intermediate step at a third height from the finFET base region that is equal to or greater than the first height and less than the second height.

16. The IC of claim 15, wherein the HV planar region second height is greater than the M/LV planar region second height.

17. The IC of claim 15, wherein the HV planar region boundary buffer area third height is substantially equal to the M/LV planar region boundary buffer area third height.

18. A method of manufacturing an integrated circuit (IC), the method comprising:
forming, in a device region of a semiconductor substrate, a fin region including one or more fin field-effect transistors (finFETs), each device region finFET including one or more fins and a gate formed to wrap around one or more tops of the one or more fins, and a planar region adjacent to the fin region, the planar region including one or more planar semiconductor device structures;
forming a seal ring region encircling the device region, the seal ring region including an inner seal ring encircling the device region and an outer seal ring encircling both the inner seal ring and the device region, the outer seal ring including a plurality of fins, each of the fins having a fin top at a first height from a fin base region adjacent to the fin, and the inner seal ring including a planar boundary buffer area adjacent to the device planar region and formed at a second height from the fin base region, the second height less than the first height.

19. The method of claim 18, wherein the device planar region is adjacent the inner seal ring and the device planar height is a third height from the outer seal fin base region, and the third height is greater than the second height, the boundary buffer area thereby providing an intermediate step from the inner seal to the device planar region.

20. The method of claim 18, wherein the first height is about 35 nm to about 45 nm, and the second height is from about 35 nm to about 45 nm.
